(19) United States
(12) Patent Application Publication
(10) Pub. No.: US 2009/0122498 A1
(43) Pub. Date: May 14, 2009

(54) CIRCUIT BOARD AND CONDUCTIVE THROUGH HOLE STRUCTURE THEREOF

(75) Inventors: Jin-cai Lan, Jiangsu Province (CN); Wen-Kang Fan, Taipei City (TW)

Correspondence Address: J C PATENTS, INC., 4 VENTURE, SUITE 250, IRVINE, CA, 92618, US

(73) Assignee: INVENTEC CORPORATION, Taipei City (TW)

(21) Appl. No.: 11/969,670

(22) Filed: Jan. 4, 2008

(30) Foreign Application Priority Data
Nov. 14, 2007 (TW) 96143022

(51) Int. Cl. H05K 1/18

(52) U.S. Cl. 361/778

(57) ABSTRACT

A circuit board having at least one through hole and including a first and a second wiring layer, an insulation layer, and a conductive through hole structure is provided. The insulation layer is disposed between the first and second wiring layers. The through hole located in the insulation layer extends from the first wiring layer to the second wiring layer. The conductive through hole structure includes at least one first pad, at least one second pad, and a conductive pattern. The first pad partially covers the edge of one opening of the through hole and connects the first wiring layer. The second pad partially covers the edge of the other opening of the through hole and connects the second wiring layer. The conductive pattern connects the first and second pads and partially covers the sidewall of the through hole.

### CROSS-REFERENCE TO RELATED APPLICATION

This application claims the priority benefit of Taiwan application serial no. 96143022, filed on Nov. 14, 2007. The entirety of the above-mentioned patent application is hereby incorporated by reference herein and made a part of this specification.

### BACKGROUND OF THE INVENTION

1. Field of the Invention

The present invention relates to a circuit board, and more particularly to a conductive through hole structure of a circuit board.

2. Description of Related Art

A conductive through hole structure is an indispensable component in a double sided circuit board and a multi-layer circuit board, for being capable of electrically connecting two layers of circuits in the double sided circuit board or the multi-layer circuit board, so as to have the two layers of circuits electrically conducted.

FIG. 1A is a schematic top view of a conventional double-layer circuit board, and FIG. 1B is a schematic cross-sectional view of FIG. 1A along Line I-I. Together referring to FIGS. 1A and 1B, the circuit board 100 includes two copper circuit layers 110a and 110b, a dielectric layer 120, and at least one conductive through hole structure 130. The dielectric layer 120 is disposed between the copper circuit layers 110a and 110b. The circuit board 100 has at least one through hole H1 located in the dielectric layer 120, and the through hole H1 extends from the copper circuit layer 110a to the copper circuit layer 110b.

The conductive through hole structure 130 disposed in the through hole H1 has two washers 132a, 132b and a conductive layer 134. The washer 132a is connected to a trace 112a of the copper circuit layer 110a, and the washer 132b is electrically connected to the copper circuit layer 110b. The conductive layer 134 completely covers the sidewall W1 of the through hole H1, and is connected between the washer 132a and the washer 132b. In this manner, the copper circuit layer 110a is electrically connected to the copper circuit layer 110b through the conductive through hole structure 130.

However, with the progress of technology, the current circuit board has been developed in a trend of having a high circuit density, and it is quite difficult to further improve the circuit density of the aforementioned circuit board 100 and other conventional circuit boards (such as multi-layer circuit boards). Therefore, how to enhance the circuit density of a circuit board is quite an issue at present.

### SUMMARY OF THE INVENTION

The present invention is directed to a circuit board, which has a conductive through hole structure capable of enhancing the circuit density of the circuit board.

The present invention is also directed to a conductive through hole structure, for enhancing the circuit density of the circuit board.

A conductive through hole structure disposed in a through hole of a circuit board is provided. The circuit board includes a first wiring layer, a second wiring layer, and an insulation layer disposed between the first wiring layer and the second wiring layer. The through hole located in the insulation layer extends from the first wiring layer to the second wiring layer. The through hole has a first opening located in the first wiring layer and a second opening located in the second wiring layer. The conductive through hole structure includes at least one first pad, at least one second pad, and a conductive pattern. The first pad partially covers an edge of the first opening, and connects the first wiring layer. The second pad partially covers an edge of the second opening, and connects the second wiring layer. The conductive pattern connects the first pad and the second pad, and partially covers the sidewall of the through hole.

A circuit board having at least one through hole and including a first wiring layer, a second wiring layer, an insulation layer, and the aforementioned conductive through hole structure is further provided. The insulation layer is disposed between the first wiring layer and the second wiring layer. The through hole located in the insulation layer extends from the first wiring layer to the second wiring layer. The through hole has a first opening located in the first wiring layer and a second opening located in the second wiring layer.

According to the present invention, the layout of the circuit board may extend into the conductive through hole structure via the conductive pattern. In this manner, the circuit density of the circuit board is further enhanced by the conductive through hole structure of the present invention.

In order to make the aforementioned and other objects, features and advantages of the present invention comprehensible, the embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic top view of a conventional double-layer circuit board.

FIG. 1B is a schematic cross-sectional view of FIG. 1A along Line I-I.

FIG. 2A is a schematic top view of a circuit board according to a first embodiment of the present invention.

FIG. 2B is a schematic three-dimensional view of the cross-section of the circuit board in FIG. 2A along Line J-J.

FIGS. 3A-3C are schematic three-dimensional views of the cross-section of the circuit board in FIG. 2B during the fabrication flow.

FIG. 4A is a schematic top view of a circuit board according to a second embodiment of the present invention.

FIG. 4B is a schematic three-dimensional view of the cross-section of the circuit board in FIG. 4A along Line K-K.

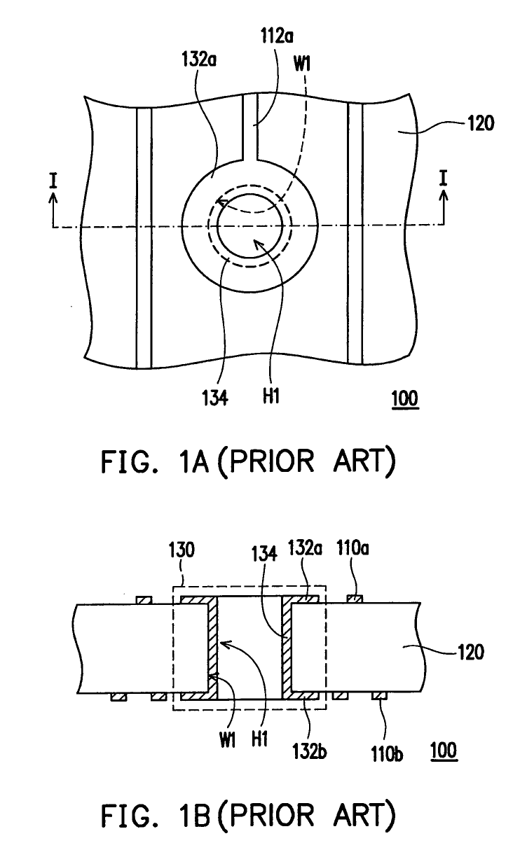

### DESCRIPTION OF EMBODIMENTS

### Embodiment One

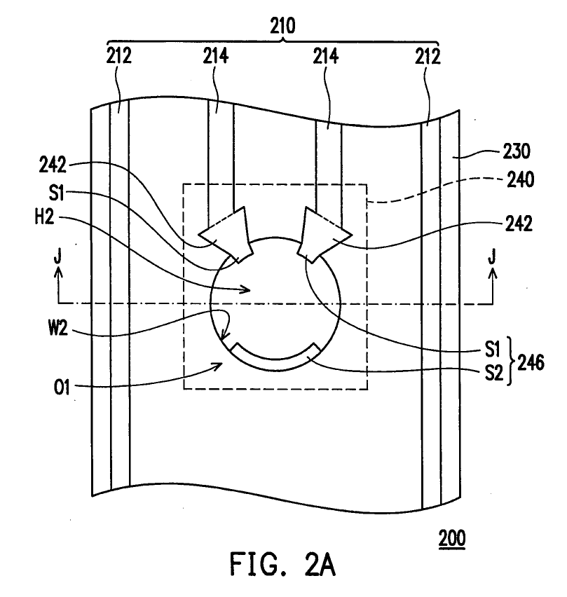

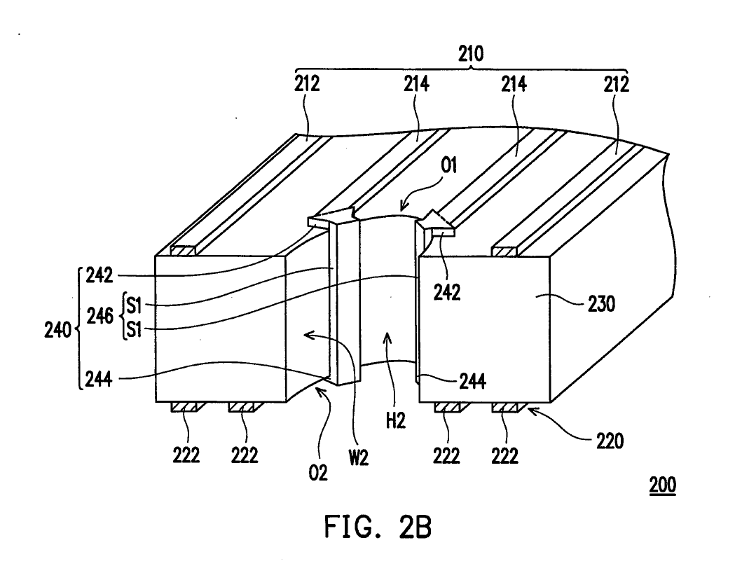

FIG. 2A is a schematic top view of a circuit board according to a first embodiment of the present invention, and FIG. 2B is a schematic three-dimensional view of the cross-section of the circuit board in FIG. 2A along Line J-J. Referring to FIGS. 2A and 2B, the circuit board 200 includes a first wiring layer 210, a second wiring layer 220, and an insulation layer 230. The insulation layer 230 is disposed between the first wiring layer 210 and the second wiring layer 220. In addition, the first wiring layer 210 may include a plurality of traces 212 and 214, and the second wiring layer 220 may include a plurality of traces 222.

The circuit board 200 has a through hole H2. The through hole H2 is located in the insulation layer 230 and extends from the first wiring layer 210 to the second wiring layer 220. Further, the through hole H2 has a first opening O1 located in the first wiring layer 210 and a second opening O2 located in the second wiring layer 220.

The circuit board 200 also includes a conductive through hole structure 240 disposed in the through hole H2. The conductive through hole structure 240 includes a plurality of first pads 242 and a plurality of second pads 244. The first pads 242 partially cover an edge of the first opening O1, and the second pads 244 partially cover an edge of the second opening O2. That is, the first pads 242 and the second pads 244 do not completely cover the edge of the first opening O1 and that of the second opening O2 respectively.

The first pads 242 connect the first wiring layer 210, and the second pads 244 connect the second wiring layer 220. In particular, the first pads 242 connect the traces 214, respectively, and the second pads 244 connect the traces 222, respectively. In this way, the first pads 242 and the first wiring layers 210 are electrically conducted, and the second pads 244 and the second wiring layers 220 are electrically conducted.

The conductive through hole structure 240 further includes a conductive pattern 246. The conductive pattern 246 connects the first pads 242 and the second pads 244, and partially covers the sidewall W2 of the through hole H2, i.e., the conductive pattern 246 partially exposes the sidewall W2. That is to say, the conductive pattern 246 does not completely cover the sidewall W2 of the through hole H2.

In this embodiment, the conductive pattern 246 may include a plurality of conductive circuits S1 and a conductive circuit S2, in which the conductive circuits S1 are not in contact with each other, nor in contact with the conductive circuit S2. That is, the conductive circuits S1 are not only separated from each other, but also separated from the conductive circuit S2, such that short circuits may not occur between the conductive circuits S1 nor between the conductive circuits S1 and the conductive circuit S2. The conductive circuits S1 connect the first pads 242 and the second pads 244, and the first pads 242 are electrically connected to the second pads 244 through the conductive circuits S1.

In this embodiment, the traces 214, the first pads 242, and the conductive circuits S1 are used to transmit a pair of differential-in signals, and the conductive circuit S2 serves as a ground circuit. The differential-in signals may be transmitted in the conductive through hole structure 240 at the same time. As such, the impedances of the traces 214, the first pads 242, and the conductive circuits S1 can be controlled to alleviate the degree of distortion of the differential-in signals, so as to ensure the accuracy of the differential-in signals.

In addition, in order to meet some requirements of circuit design, such as impedance matching, impedance control, and RC delay, the first pads 242 and the second pads 244 can be designed to have various shapes, for example, trapezoid (as shown in FIGS. 2A and 2B), rectangle, square, triangle, circle, ellipse, and other geometric shapes. Therefore, the shapes of the first pads 242 and the second pads 244 in FIGS. 2A and 2B are only used as an example for illustration, instead of limiting the present invention.

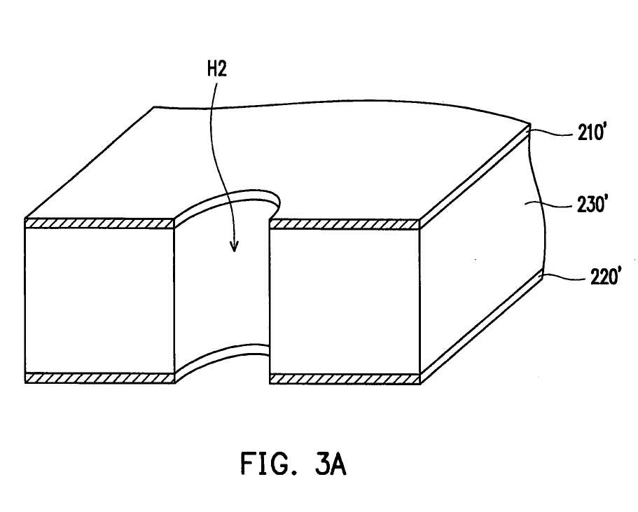

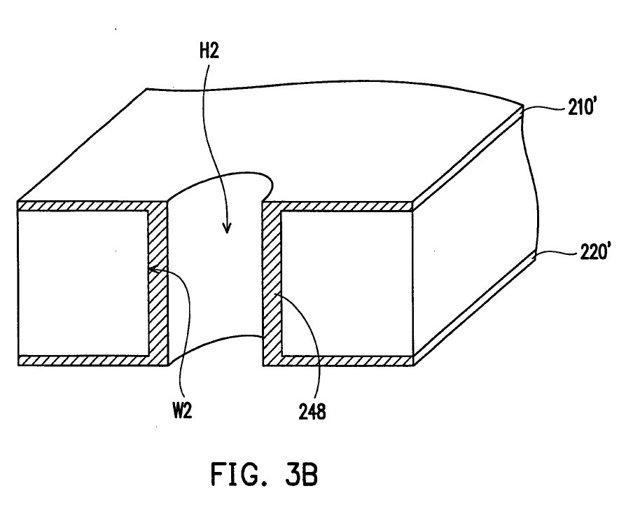

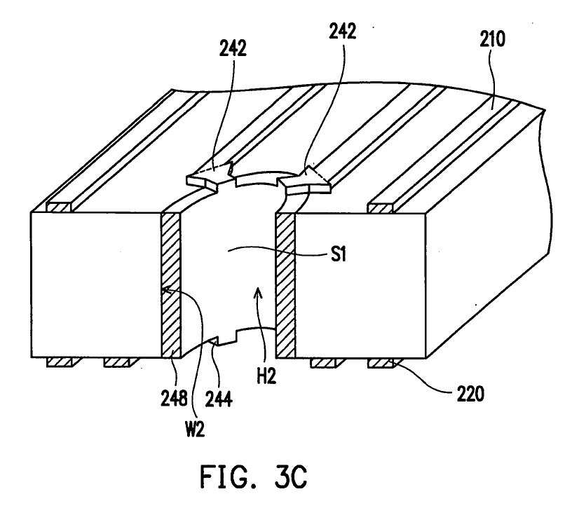

Only the structure of the circuit board 200 is introduced in detail above, and no illustration is given for the method of fabricating the circuit board 200. Thus, a method of fabricating the circuit board 200 will be illustrated in detail below with reference to FIGS. 3A-3B.

FIGS. 3A-3C are schematic three-dimensional views of the cross-section of the circuit board in FIG. 2B during the fabrication flow. First, referring to FIG. 3A, at least one through hole H2 is formed in a substrate 102. In particular, the substrate 102 has a first conductive layer 210′, a second conductive layer 220′, and an insulating material layer 230′. The insulating material layer 230′ is disposed between the first conductive layer 210′ and the second conductive layer 220′, and the through hole H2 extends from the first conductive layer 210′ to the second conductive layer 220′. In this embodiment, the substrate 102 may be a copper clad laminate (CCL) or other suitable substrates, and the through hole H2 may be formed by means of mechanical drilling, laser drilling, or other drilling processes.

Next, referring to FIG. 3B, a plating through hole (PTH) process is performed to form a conductive material layer 248 on the sidewall W2 of the through hole H2, and the conductive material layer 248 completely covers the sidewall W2 of the through hole H2. In addition, the PTH process may include an electroplating process and an electroless plating process.

Afterward, referring to FIGS. 3B and 3C, a portion of the first conductive layer 210′ and a portion of the second conductive layer 220′ are removed to form the first wiring layer 210 and the second wiring layer 220. The above removal method may be a lithography and etching process or other suitable processes. Meanwhile, a plurality of first pads 242 and a plurality of second pads 244 are also formed after a portion of the first conductive layer 210′ and a portion of the second conductive layer 220′ are removed.

Then, sequentially referring to FIGS. 3C and 2B, a portion of the conductive material layer 248 in the through hole H2 is removed to form a conductive pattern 246. The portion of the conductive material layer 248 may be ablated with a laser or milled by a drilling bit of a small diameter. In this manner, the conductive circuit S2 is formed, and meanwhile a conductive through hole structure 240 is also formed.

Further, in a typical embodiment, the aperture of the through hole H2 is larger than 1 mm. As such, the conductive pattern 246 may be formed through a 3D numerical control machine. In particular, the 3D numerical control machine has a min-cutter, which can go deep into the through hole H2, and carve the conductive pattern 246 on the conductive material layer 248.

It should be noted that, the 3D numerical control machine may not only carve the conductive circuits S1 and S2 in a longitudinal direction, but also carve the conductive circuits in transverse or other directions. That is, the 3D numerical control machine may form a conductive pattern 246 of various shapes. For example, the conductive pattern 246 may be a conductive circuit, or in a square, trapezoidal, triangular, circular, or other geometric patterns. Therefore, it should be emphasized herein that, the shape of the conductive pattern 246 in FIG. 2B is only used as an example for illustration, instead of limiting the present invention.

Further, in other embodiments not shown, a filling material may be filled into the through hole H2. As such, electrical parameters of the conductive through hole structure 240, such as impedance and capacitance, can be regulated to meet the requirements of diversified circuit design of the circuit board 200.

It should be stressed that, the circuit board 200 in FIG. 2B is a double sided circuit board, and in other embodiments not shown, the circuit board 200 may also be a multi-layer circuit board. Besides, the conductive through hole structure 240 may also be applied in a multi-layer circuit board. For example, the conductive through hole structure 240 may serve as a conductive path between multi-layer circuits in the multi-layer circuit board. Therefore, the circuit board 200 in FIG. 2B is only used as an example for illustration, instead of limiting the present invention.

### Embodiment Two

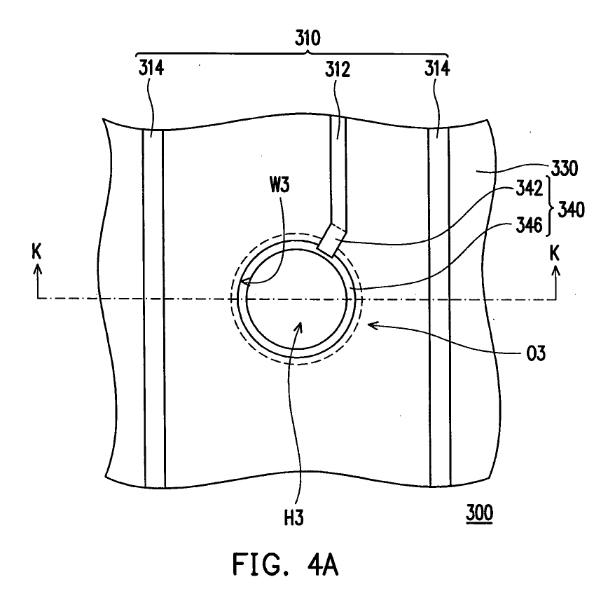

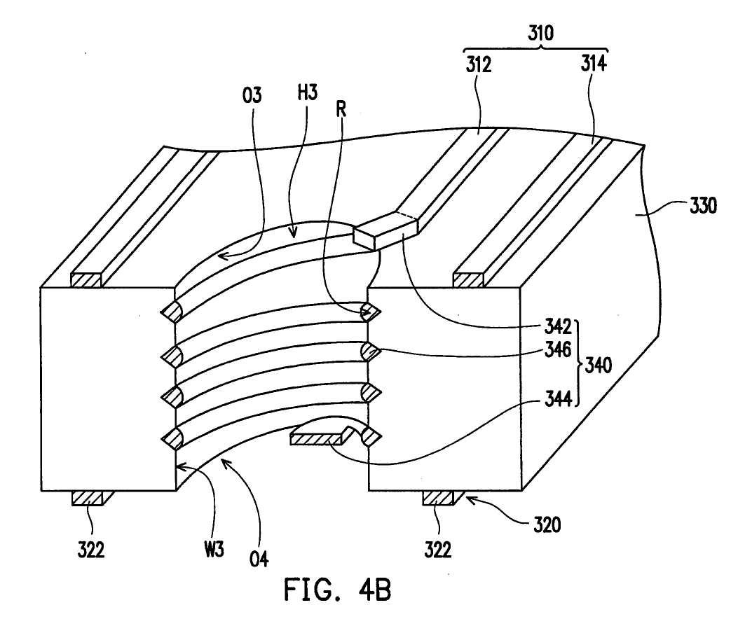

FIG. 4A is a schematic top view of a circuit board according to a second embodiment of the present invention, and FIG. 4B is a schematic three-dimensional view of the cross-section of the circuit board in FIG. 4A along Line K-K. Referring to FIGS. 4A and 4B, the circuit board 300 of the second embodiment includes a first wiring layer 310, a second wiring layer 320, an insulation layer 330, and a conductive through hole structure 340, and has a through hole H3.

The insulation layer 330 is disposed between the first wiring layer 310 and the second wiring layer 320. The first wiring layer 310 may include a trace 312 and a plurality of traces 314, and the second wiring layer 320 may include a plurality of traces 322. The through hole H3 is located in the insulation layer 330, and extends from the first wiring layer 310 to the second wiring layer 320. Further, the through hole H3 has a first opening O3 located in the first wiring layer 310 and a second opening O4 located in the second wiring layer 320.

The conductive through hole structure 340 disposed in the through hole H3 has a first pad 342, a second pad 344, and a conductive pattern 346. The conductive pattern 346 electrically connects the first pad 342 and the second pad 344, and partially covers the sidewall W3 of the through hole H3.

The circuit board 300 of this embodiment is similar to the circuit board 200 of the first embodiment, so only the difference between the circuit board 300 and the circuit board 200 is illustrated below. The difference between the circuit board 300 and the circuit board 200 is that, the conductive pattern 346 is a conductive circuit helically distributed on the sidewall W3 of the through hole H3.

Accordingly, the conductive through hole structure 340 may serve as an inductive component through the conductive pattern 346, and in other embodiments not shown, a filling material may be filled into the through hole H3. In this manner, the inductance value of the conductive through hole structure 340 can be regulated to meet some requirements of circuit design.

In a method of forming the conductive pattern 346, a tapping process is first performed on the through hole H3 to form a threaded recess R. Afterward, a PTH process is performed to form a conductive material layer on the sidewall W3.

After the conductive material layer is formed, an etching process is performed to remove a portion of the conductive material layer while remain a portion of the conductive material layer in the threaded recess R. As the conductive material layer formed by the PTH process is thicker in the threaded recess R, the portion of the conductive material layer in the threaded recess R remains after the etching process. Thus, the conductive pattern 346 is formed.

Moreover, in another method of forming the conductive pattern 346, a PTH process is performed first, and then a tapping process is carried out to form a helically distributed conductive circuit. Thereby, the conductive pattern 346 is also formed.

In view of the above, as the conductive through hole structure provided by the present invention has a conductive pattern partially covering the sidewall of the through hole, the layout of the circuit board may extend into the conductive through hole structure according to the present invention. As such, the present invention further enhances the circuit density of the circuit board to meet the current developing trend of high circuit density.

Further, through the above conductive pattern, the conductive through hole structure of the present invention can provide various conductive paths to transmit different signals simultaneously. Thereby, the present invention can provide diversified circuit design of the circuit board and meet different demands on products.

In addition, as the conductive through hole structure of the present invention can provide various conductive paths and the first and second pads may be designed to have various shapes, the present invention can meet some requirements of circuit design, such as impedance matching, impedance control, and RC delay. In this manner, the present invention can reduce noises generated by the circuit board, so as to ensure the accuracy of the signals (such as differential-in signals) transmitted in the circuit board.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A conductive through hole structure, disposed in a through hole of a circuit board, wherein the circuit board has a first wiring layer, a second wiring layer, and an insulation layer disposed between the first wiring layer and the second wiring layer, the through hole located in the insulation layer extends from the first wiring layer to the second wiring layer, and the through hole has a first opening located in the first wiring layer and a second opening located in the second wiring layer, the conductive through hole structure comprising:
at least one first pad, partially covering the edge of the first opening and connecting the first wiring layer;
at least one second pad, partially covering the edge of the second opening and connecting the second wiring layer; and
a conductive pattern, connecting the first pad and the second pad and partially covering the sidewall of the through hole.

2. The conductive through hole structure as claimed in claim 1, wherein the conductive pattern is a conductive circuit, and the first pad is electrically connected to the second pad through the conductive circuit.

3. The conductive through hole structure as claimed in claim 2, wherein the conductive circuit is helically distributed on the sidewall of the through hole.

4. The conductive through hole structure as claimed in claim 1, further comprising a plurality of the first pads and a plurality of the second pads, wherein the conductive pattern has a plurality of conductive circuits, one of the conductive circuits connects one of the first pads and one of the second pads, and the conductive circuits are not in contact with each other.

5. A circuit board, having at least one through hole, comprising:
a first wiring layer;
a second wiring layer;
an insulation layer, disposed between the first wiring layer and the second wiring layer, wherein the through hole located in the insulation layer extends from the first wiring layer to the second wiring layer, and the through hole has a first opening located in the first wiring layer and a second opening located in the second wiring layer;
a conductive through hole structure, comprising:
at least one first pad, partially covering the edge of the first opening and connecting the first wiring layer;
at least one second pad, partially covering the edge of the second opening and connecting the second wiring layer; and
a conductive pattern, connecting the first pad and the second pad and partially covering the sidewall of the through hole.

6. The circuit board as claimed in claim 5, wherein the conductive pattern is a conductive circuit, and the first pad is electrically connected to the second pad through the conductive circuit.

7. The circuit board as claimed in claim 6, wherein the conductive circuit is helically distributed on the sidewall of the through hole.

8. The circuit board as claimed in claim 5, wherein the conductive through hole structure further comprises a plurality of the first pads and a plurality of the second pads, the conductive pattern has a plurality of conductive circuits, one of the conductive circuits connects one of the first pads and one of the second pads, and the conductive circuits are not in contact with each other.
